(19) United States
(12) Patent Application Publication
(10) Pub. No.: US 2015/0173224 A1
(43) Pub. Date: Jun. 18, 2015

(54) COVERING ASSEMBLY FOR A PORTABLE ELECTRONIC DEVICE

(71) Applicant: Thomas A. Jaffee, Boca Raton, FL (US)

(72) Inventor: Thomas A. Jaffee, Boca Raton, FL (US)

(73) Assignee: Thomas A. Jaffee, Boca Raton, FL (US)

(21) Appl. No.: 14/107,380

(22) Filed: Dec. 16, 2013

(51) Int. Cl. H05K 5/03

(52) U.S. Cl. CPC H05K 5/03

(57) ABSTRACT

A cover assembly for a portable electronic device including a top cover attached across the top section of the portable electronic device and a bottom cover attached across the bottom section of the portable electronic device. The top cover includes a first base body configured to receive base portion of the top section of the portable electronic device, plurality of first corner bodies attached to each corner of said first base body for receiving top section corners of the portable electronic device, a first top body connected to the first base body and the plurality of corner bodies configured for receiving top section of the portable electronic device. Further, the top cover includes one or more adhesive layers for maintain the position of the top section within the top cover and one or more apertures for allowing access to ports/buttons/camera etc. Similarly, the bottom section is attached across the bottom cover.

### BACKGROUND OF THE INVENTION

1. Field of the Invention

The present invention generally relates to a protection casing for a portable electronic device, and more particularly relates to a covering assembly attached across the top and the bottom of a portable electronic device for protecting from damage.

2. Description of Related Art

With the increase in the cost and fragility of mobile devices, most users have a need to protect their mobile devices from accidental damage. Mobile covers are the most common way to protect mobile devices from any accidental damages. Approximately one billion mobile devices are expected to be sold in 2014, and most will likely have one of the various different types of mobile covers. Further, mobile covers are often purchased for their aesthetic appeal as well as their functional and protective benefits.

There are various types of mobile device covers, such as: a pocket style that envelops the device when stowed and requires the device to be removed from the pocket in order to use the device; a flip-cover style, which also fully envelops the phone when stowed and requires the top cover to be folded away from the screen in order to use the device; and a body-cover style that envelops all parts of the device except the screen. Mobile device manufacturers go to great lengths to make the devices thinner and lighter, yet the aforementioned styles of cases add undesirable bulk and weight, which for most users, is unnecessary.

Another cover style covers only the four corners of the device. This style is less bulky, but leaves the top and bottom portions of the device unprotected with no functional benefit since most users do not hold the top or bottom of their devices. Therefore, there is a need for a covering assembly that protects the portable electronic device from typical accidental drops, and further allows the user to hold the slimmer uncovered portion of their device.

### SUMMARY OF THE INVENTION

In accordance with the teachings of the present invention, a covering assembly for protecting a portable electronic device is provided.

An object of the present invention is to provide a cover assembly including a top cover attached to the top section of the portable electronic device and a bottom cover attached to the bottom section of the portable electronic device. The top cover includes a first base body configured to receive base portion of the top section of the portable electronic device, plurality of first corner bodies attached to each corner of said first base body for receiving top section corners of the portable electronic device, a first top body connected to the first base body and the plurality of corner bodies configured for receiving top section of the portable electronic device.

The top cover further includes one or more first adhesive layers attached to the first base body and to each of the plurality of first corner bodies for maintaining the position of the top section of the portable electronic device inside the first base body, the plurality of first corner bodies, and the first top body. The top cover further includes one or more first apertures configured on the first base body and the first top body for allowing access to each of the one or more ports formed on the portable electronic device and for unobstructed use of camera of the portable electronic device.

The bottom cover includes a second base body configured to receive base of the portable electronic device from the bottom section, plurality of second corner bodies attached to each corner of the second base body configured to receive bottom section of the portable electronic device, one or more second adhesive layers attached to the second base body and the plurality of second corner bodies for maintaining the position of bottom section of the portable electronic device within the second base body, and the plurality of second corner bodies; and the bottom cover further includes one or more first apertures configured on the first base body and the first top body for allowing access to each of the one or more ports formed on the portable electronic device, further for providing unobstructed use of speakers of the portable electronic device.

Another object of the present invention is to provide one of the first apertures on top cover and one of the second apertures on bottom cover for access to either a charging port or one or more sensors or headphone port or cable attachment port or flash unit.

Another object of the present invention is to provide a covering assembly for protecting the portable electronic devices, such as mobile phones and tablet computers made by companies such as Apple®, Samsung®, HTC®, etc. from accidental damage.

Further features and advantages of the present invention, as well as the structure and operation of various embodiments of the present invention, are described in detail below with reference to the accompanying drawings.

### BRIEF DESCRIPTION OF DRAWINGS

FIG. 1 illustrates an exploded view of a covering assembly for a portable electronic device in accordance with a preferred embodiment of the present invention;

FIG. 2 illustrates a back perspective view of the covering assembly for a portable electronic device showing top cover in according with a preferred embodiment of the present invention;

FIG. 3 illustrates another back perspective view of the covering assembly for a portable electronic device showing top cover in according with another preferred embodiment of the present invention;

FIG. 4 illustrates another back perspective view of the covering assembly for a portable electronic device showing top cover in according with another preferred embodiment of the present invention;

FIG. 5 illustrates a back perspective view of the covering assembly for a portable electronic device showing bottom cover in according with a preferred embodiment of the present invention;

FIG. 6 illustrates another back perspective view of the covering assembly for a portable electronic device showing bottom cover in according with another preferred embodiment of the present invention; and

FIG. 7 illustrates another back perspective view of the covering assembly for a portable electronic device showing bottom cover in according with another preferred embodiment of the present invention

### DETAILED DESCRIPTION OF DRAWINGS

While this technology is illustrated and described in a preferred embodiment, a covering assembly attached to the portable device for protecting from accidental damage may be produced in many different configurations forms, and materials. There is depicted in the drawings, and will herein be described in detail, as a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the technology described herein.

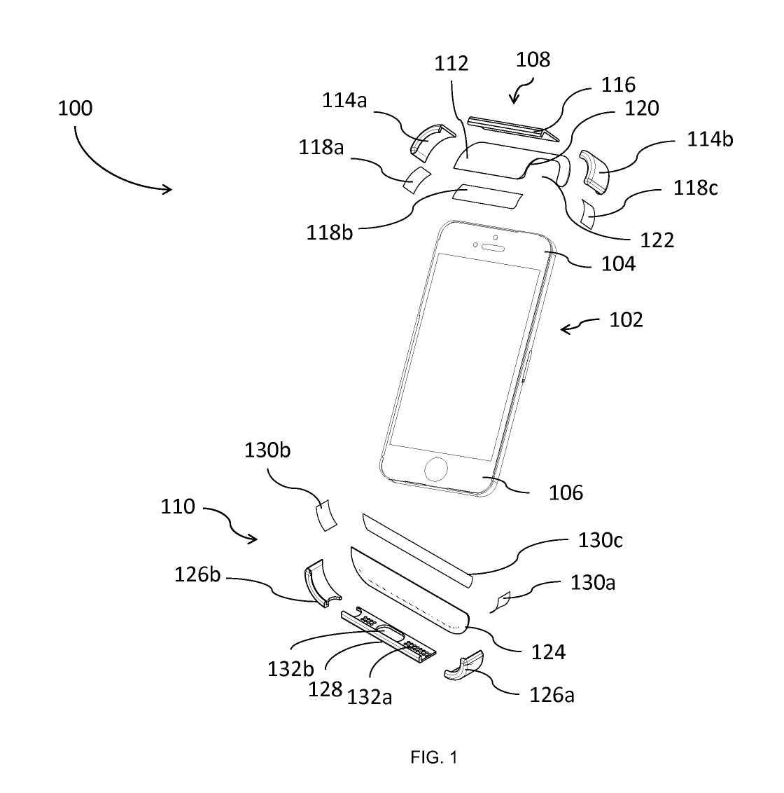

FIG. 1 illustrates an exploded view of a covering assembly 100 for a portable electronic device 102. The portable electronic device 102 includes a top section 104 and a bottom section 106. The covering assembly 100 includes a top cover 108 attached to the top section 104 of the portable electronic device 102 and a bottom cover 110 attached to the bottom section 106 of the portable electronic device 102.

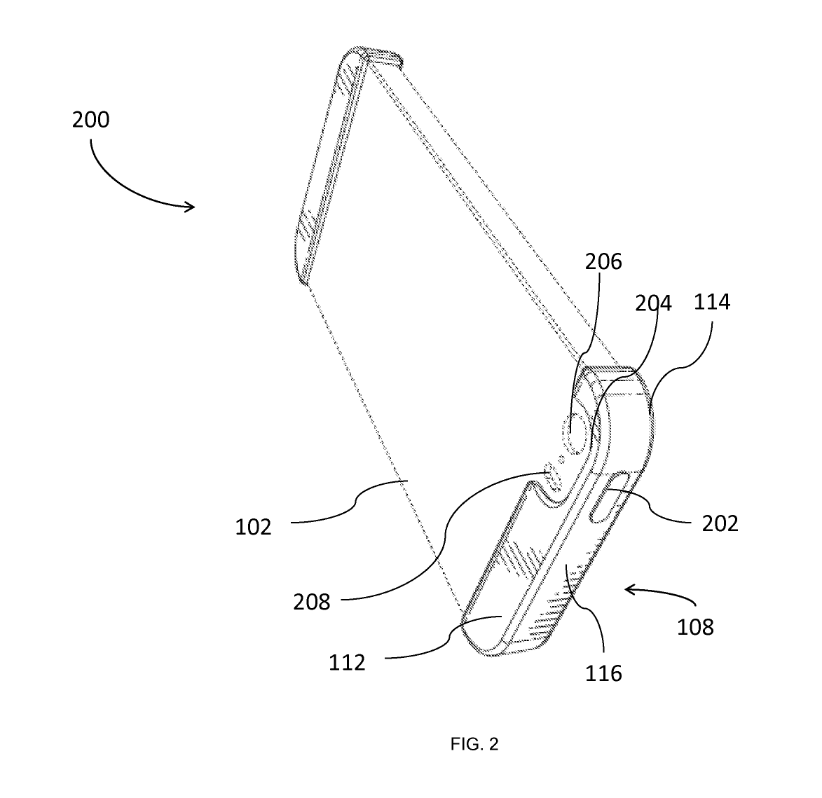

In a preferred embodiment of the present invention, the top cover 108 includes a first base body 112 is configured to receive the top section 104 of the portable electronic device 102, plurality of first corner bodies 114 such as 114a, 114b attached to each corner of the first base body 112 is for receiving the corners of the top section 104 of the portable electronic device 102, a first top body 116 is connected to the first base body 112 and the plurality of corner bodies 114 is configured to maintain the top section 104 on the first base body 112. The first base body 112, the plurality of first corner bodies 114 and the first top body 116 is shown and explained in detail in conjunction FIG. 2 to FIG. 4 of the present invention.

The top cover 102 further includes one or more adhesive layers 118 such as 118a, 118b and 118c attached to the first base body 112 and to each of the first corner body 114a and 114b for maintaining the position of the top section 104 of the portable electronic device 102 within the first base body 112 and the plurality of corner bodies 114. Examples of the portable electronic device 102 are phones and tablet computers from different companies. However, it will be apparent to those skilled in the art that various other portable electronic devices 102 may be used without deviating from the scope of the present invention.

The top cover 102 further includes one or more first apertures 120 configured on the first base body 112 for allowing access to each of the one or more ports (not shown in FIG. 1) formed on the portable electronic device 102 and further provides an opening 122 for unobstructed use of camera (not shown in FIG. 1) of the portable electronic device 102. The one or more first apertures 120 are explained in detail in conjunction with FIG. 2 of the present invention. Examples of the one or more adhesive layers 118 include but not limited to double coated tape such as 3M 4658F, or 3M 444, or 3M 9627, etc.

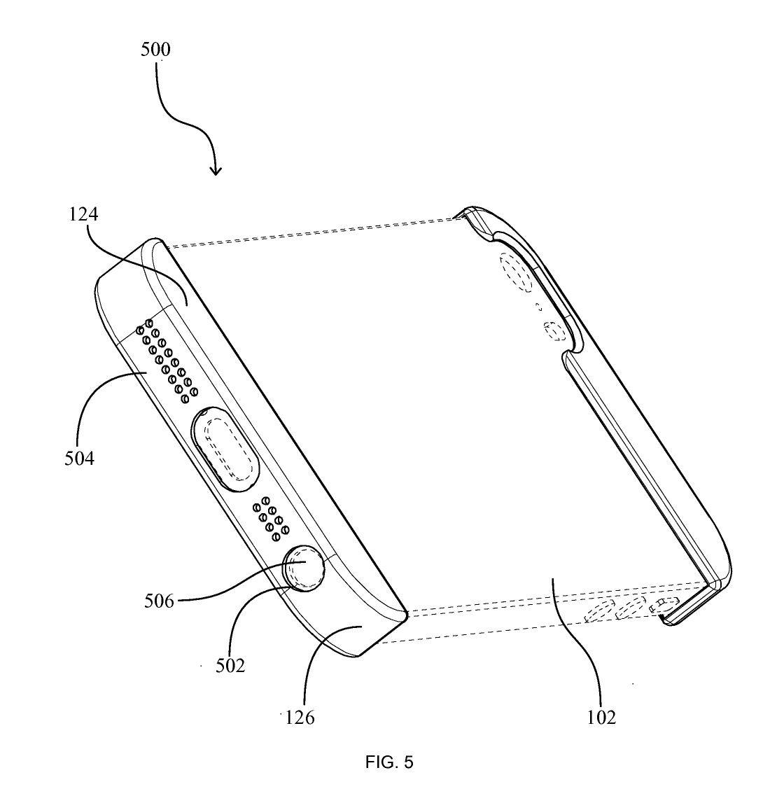

The bottom cover 110 is attached across the bottom section 106 of the portable electronic device 102. The bottom cover 110 includes a second base body 124 configured to receive base of the portable electronic device 102 from the bottom section 106, plurality of second corner bodies 126 such as 126a, 126b attached to each corner of the second base body 124 is configured for receiving the corners of the bottom section 106 of the portable electronic device 102. The bottom cover 110 further includes a first bottom body 128 connected to the second base body 124 is configured for maintaining the bottom section 106 on the second base body 124. The second base body 124, the plurality of second corner bodies 126 and the first bottom body 128 is shown and explained in detail in conjunction with FIG. 5 to FIG. 7 of the present invention.

The bottom cover 110 further includes one or more second adhesive layers 130 such as 130a, 130b attached to each of the plurality of second corner bodies 126a and 126b respectively and one of the one or more second adhesive layers 130c is attached to the second base body 124 for maintaining the position of the bottom section 106 of the portable electronic device 102 within the second base body 124 and the plurality of second corner bodies 126.

The bottom cover 110 further includes one or more second apertures 132 such as 132a and 132b configured on the first bottom body 128. One of the one or more second apertures 132a provides an opening for speakers of the portable electronic device. Further, one of the one or more second apertures 132b provides access to the cable attachment port of the portable electronic device 102. The one or more apertures 132 are shown and explained in detail in conjunction with FIG. 5 to FIG. 7 of the present invention.

FIG. 2 illustrates a back perspective view of the covering assembly 100 attached to the portable electronic device 102. In a preferred embodiment of the present invention, the first base body 112 is shaped according to the top section (inside the top cover 108) of the portable electronic device 102. For exemplary purposes as shown in FIG. 1, the portable electronic device 102 is an Apple® Phone.

The plurality of first corner bodies 114 are curved according to the shape of the portable electronic device 102. In a preferred embodiment of the present invention, one of the one or more first apertures (not shown in FIG. 2) is formed on the first top body 116 for allowing access to the on/off button 202. Further, one of the one or more first apertures 204 is formed on the first base body 114 for allowing unobstructed use of camera 206 and flash unit 208.

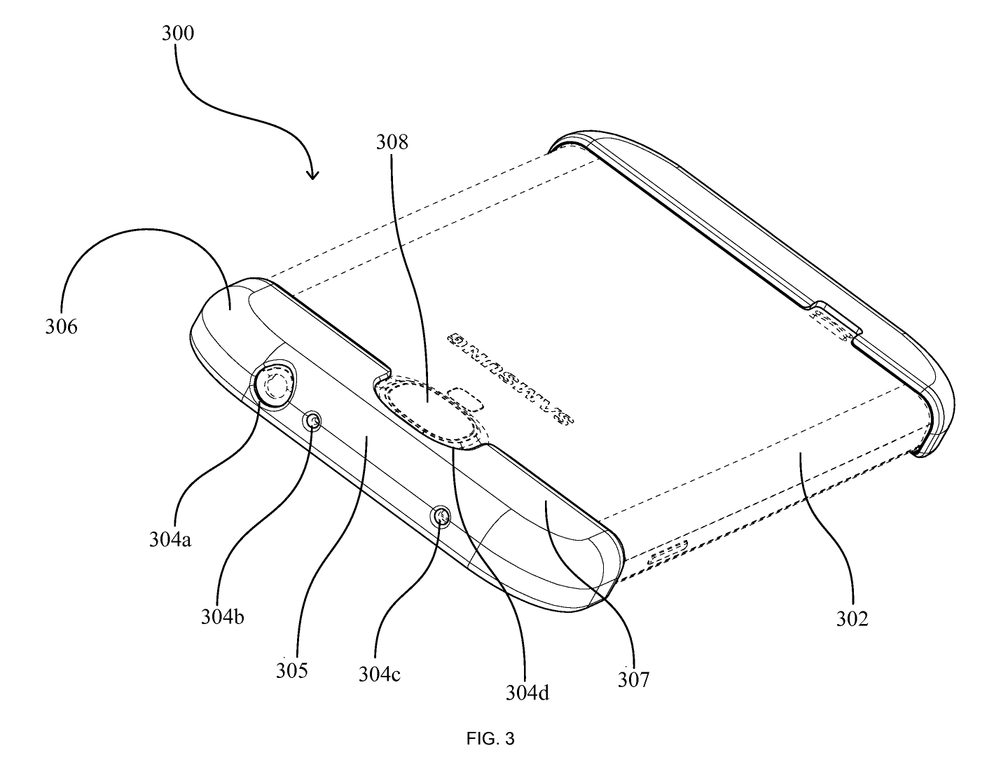

FIG. 3 illustrates another back perspective view of the covering assembly 300 attached to the portable electronic device 302 in accordance with another preferred embodiment of the present invention. One of the one or more first apertures 304 such as 304a formed on the first top body 305 allows access to the headphone port 306. Further, plurality of the one or more apertures 304 such as 304b and 304c on the first top body 305 allow access to the sensors present on the top section (inside the first base body 307 and the first top body 305) of the portable electronic device 302.

In another preferred embodiment of the present invention, the one of the one or more apertures 304 such as 304d formed on the first base body 307 allow unobstructed use of the camera 308. The portable electronic device 302 is a smartphone from Samsung®. However, it will be apparent to those skilled in the art that various other portable electronic devices 302 may also be used from different companies having different shape, size, and configuration, without deviating from the scope of the present invention.

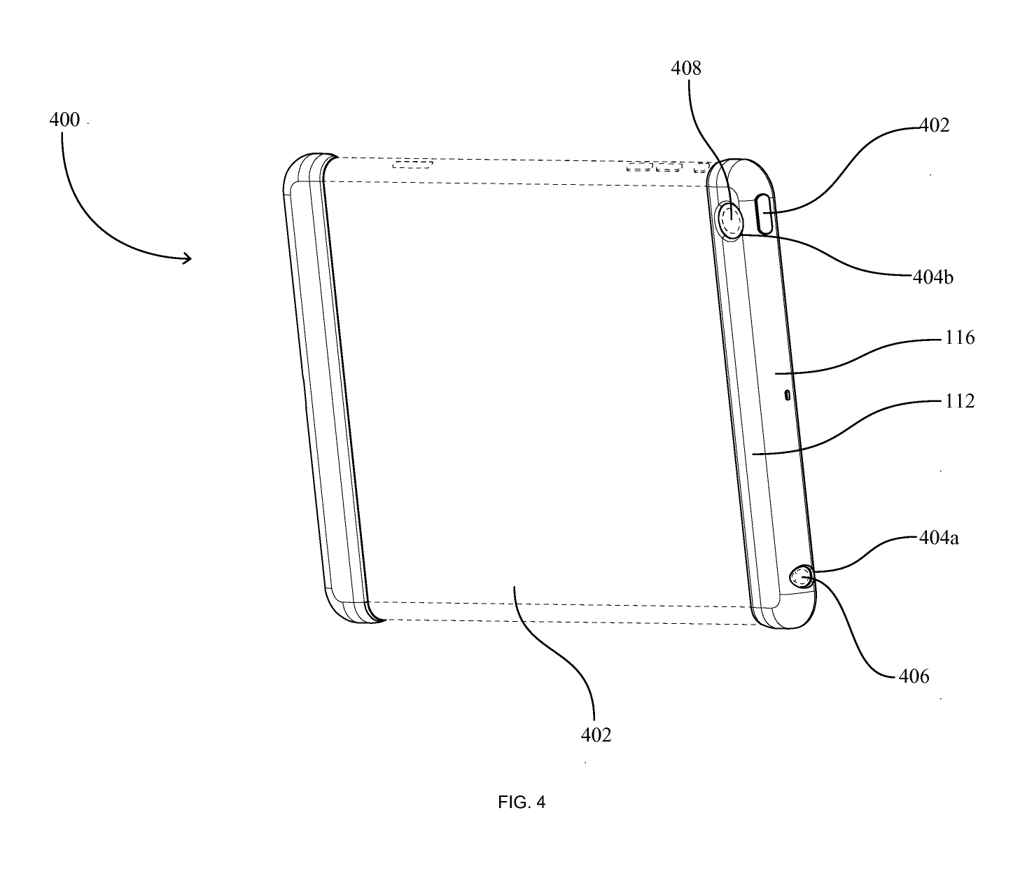

FIG. 4 illustrates another back perspective view of the covering assembly 400 attached to the portable electronic device 402. In a preferred embodiment of the present invention, one of the one or more first apertures (not shown in FIG. 4) is formed on the first top body 116 for allowing access to the on/off button 402. Further, one of the one or more first apertures 404 such as 404a is formed on the first top body 116 for allowing access to the headphone port 406 and one of the one or more first apertures 404 such as 404b is formed on the first base body 112 for allowing unobstructed use of the camera 408. The shape of the one of the one or more first apertures 404b is circular to allow access of the camera 408. The shape of the first base body 112 and the first top body 116 is formed according to the shape of the portable electronic device 402. In another preferred embodiment of the present invention, the portable electronic device 402 is an iPad mini tablet computer.

FIG. 5 illustrates a back perspective view of the covering assembly 500 attached to the portable electronic device 102 in accordance with another preferred embodiment of the present invention. The second base body 124 is shaped according the bottom section (inside the bottom cover 110) of the portable electronic device 102. For exemplary purposes as shown in FIG. 1, the portable electronic device 102 is an Apple® Phone. In a preferred embodiment of the present invention, the plurality of second corner bodies 126 is curved according to the shape of the portable electronic device 102. In a preferred embodiment of the present invention, one of the one or more second apertures 502 is formed on the first bottom body 504 for allowing access to the headphone port 506.

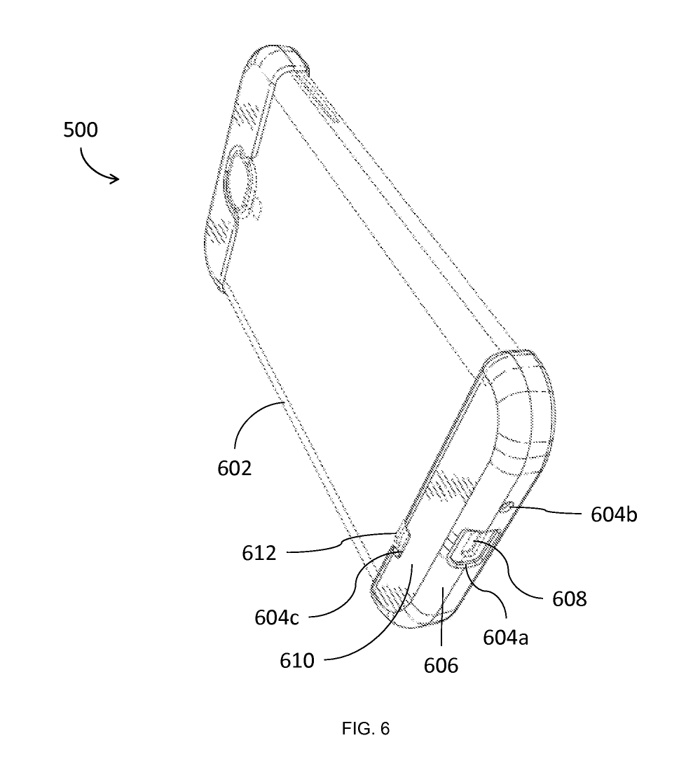

FIG. 6 illustrates another back perspective view of the covering assembly 600 attached to the portable electronic device 602 in accordance with another preferred embodiment of the present invention. One of the one or more second apertures 604 such as 604a, 604b formed on the first bottom body 606 to provide access to the cable attachment port 608 and to the sensor respectively of the portable electronic device 602. Further, one of the one or more second apertures 604c is formed on the second base body 610 to provide an opening for the speakers 612 of the portable electronic device 602. The portable electronic device 602 is a phone from Samsung® in accordance with another preferred embodiment of the present invention.

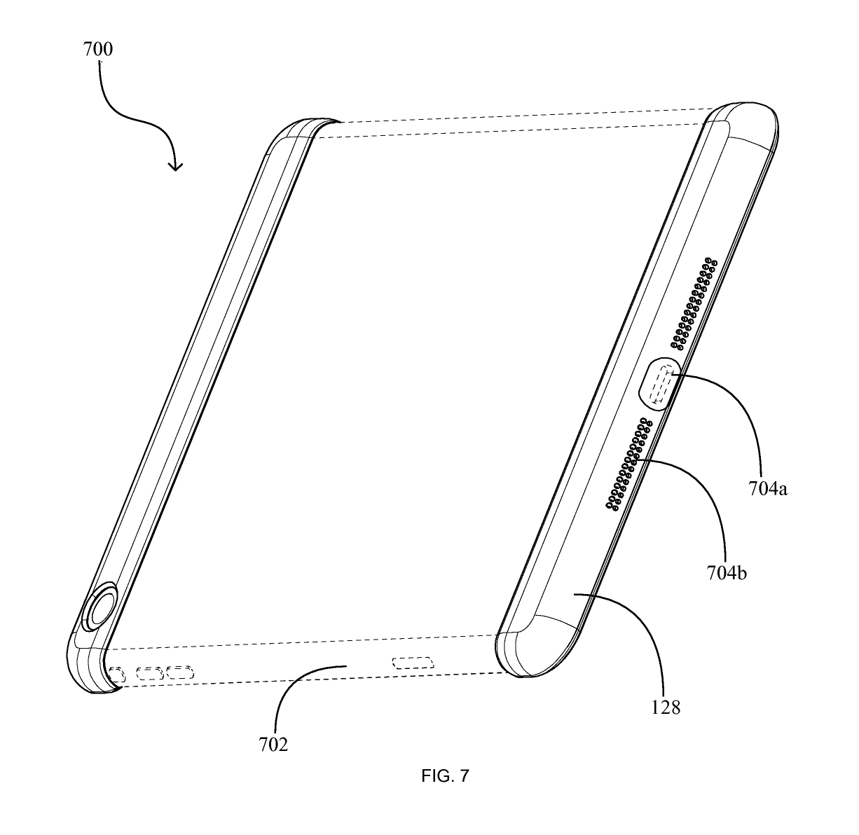

FIG. 7 illustrates another back perspective view of the covering assembly 700 attached to the portable electronic device 702. In another preferred embodiment of the present invention, one of the one or more second apertures 704 such as 704a and 704b are formed on the first bottom body 128 for allowing access to cable attachment port and the unobstructed use of speakers, respectively. In another preferred embodiment of the present invention, the portable electronic device 702 is an iPad.

The present invention provides various advantages over the currently available products. The present invention allows users to hold the slimmest section of the portable electronic device which is not provided by the current casing assembly. Further, the present invention targets the specific areas of the device that are required to be protected.

There has thus been shown and described a covering assembly which fulfills all the objects and advantages sought there for. Many changes, modifications, variations and other uses and applications of the subject invention will, however, become apparent to those skilled in the art after considering this specification and the accompanying drawings which disclose the preferred embodiments thereof. All such changes, modifications, variations and other uses and applications which do not depart from the spirit and scope of the invention are deemed to be covered by the invention, which is to be limited only by the claims which follow.

1. A covering assembly for a portable electronic device, wherein the portable electronic device comprising a top section and a bottom section, said covering assembly comprising:
a top cover attached across the top section of the portable electronic device, said top cover comprising:
a first base body configured to receive the top section of the portable electronic device;
plurality of first corner bodies attached to each corner of said first base body, said plurality of first corner bodies configured to receive corners of the top section of the portable electronic device;
a first top body connected to said first base body and said plurality of corner bodies, said first top body configured to maintain the top section of the portable electronic device on said first base body;
one or more first adhesive layers attached to said first base body and to each of said plurality of corner bodies for maintaining the position of the top section of the portable electronic device within said first base body and said plurality of first corner bodies; and
one or more first apertures configured on said first base body and said first top body for allowing access to each of the one or more ports and for providing an opening for unobstructed use of camera of the portable electronic device;
a bottom cover attached across the bottom section of the portable electronic device, said bottom cover comprising:
a second base body configured to receive base of the portable electronic device from the bottom section;
plurality of second corner bodies attached to each corner of said second base body, plurality of second corner bodies configured to receive bottom section corners of the portable electronic device;
a first bottom body connected to said second base body and said plurality of second corner bodies, said first bottom body configured to receive bottom section of the portable electronic device;
one or more second adhesive layers attached to said second base body and said plurality of second corner bodies for maintaining the position of bottom section of the portable electronic device inside said second base body and said plurality of second corner bodies; and
one or more second apertures configured on said second base body and said first bottom body for allowing access to each of the one or more ports and unobstructed use of speakers of the portable electronic device.

2. The covering assembly according to claim 1 wherein at least one of said one or more first apertures allows access to the charging port of the portable electronic device.

3. The covering assembly according to claim 1 wherein at least one of said one or more first apertures allow access to the one or more sensors on the portable electronic device.

4. The covering assembly according to claim 1 wherein at least one of said one or more first apertures allow access to the headphone port of the portable electronic device.

5. The covering assembly according to claim 1 wherein at least one of said one or more second apertures allow access to the cable attachment port of the portable electronic device.

6. The covering assembly according to claim 1 wherein at least one of said one or more second apertures allow access to the headphone port of the portable electronic device.

7. The covering assembly according to claim 1 wherein at least one of said one or more second apertures allow access to the charging port of the portable electronic device.

8. The covering assembly according to claim 1 wherein at least one of said one or more second apertures allow access to the one or more sensors on the portable electronic device.

9. The covering assembly according to claim 1 wherein at least one of said one or more second apertures allow access to the headphone port of the portable electronic device.

10. The covering assembly according to claim 1 wherein at least one of said one or more first apertures allows access to the cable attachment port of the portable electronic device.

11. The covering assembly according to claim 1 wherein at least one of said one or more first apertures allows access to unobstructed use of the flash unit of the portable electronic device.

12. The covering assembly according to claim 1 wherein at least one of said one or more second apertures allow access to unobstructed use of the flash unit of the portable electronic device.
